(19) United States
(12) Patent Application Publication
(10) Pub. No.: US 2007/0178611 A1
(43) Pub. Date: Aug. 2, 2007

(54) Semiconductor wafer having measurement area feature for determining dielectric layer thickness

(76) Inventor: Shoaib Zaidi, Poughkeepsie, NY (US)

Correspondence Address: DICKE, BILLIG & CZAJA, FIFTH STREET TOWERS, 100 SOUTH FIFTH STREET, SUITE 2200, MINNEAPOLIS, MN, 55402, US

(21) Appl. No.: 11/343,052

(22) Filed: Jan. 30, 2006

(51) Int. Cl. H01L 21/66

(52) U.S. Cl. 438/14

(57) ABSTRACT

A semiconductor wafer includes a first dielectric layer, a second dielectric layer contacting the first dielectric layer, and a measurement area feature. The measurement area feature is laterally enclosed by the second dielectric layer. The measurement area feature is adapted to be used for determining a thickness of the first dielectric layer, and the measurement area feature includes a mixture of at least two materials.

### BACKGROUND

Semiconductor wafers are used in the fabrication of electronic devices. Semiconductor wafers typically include multiple layers in which device features, such as transistors, memory cells, etc. are fabricated. It is common for one or more of the multiple layers to include dielectric material, such as an oxide film. Typically, after depositing the dielectric material on a semiconductor wafer, the dielectric material is polished or planarized to a specified thickness.

Depositing dielectric films over other dielectric films on a semiconductor wafer to fabricate multilayer dielectric stacks is common in the manufacture of electronic devices. Multilayer dielectric stacks are used in the fabrication of electronic devices such as Dynamic Random Access Memory (DRAM), Static Random Access Memory (SRAM), Phase-Change Memory (PCM), Magnetic Random Access Memory (MRAM), Flash, microprocessors, Application Specific Integrated Circuits (ASICs), Field Programmable Gate Arrays (FPGAs), and other electronic devices.

To determine the thickness of a polished or planarized dielectric material layer or film, optical techniques such as ellipsometry or reflectometry are typically used. If, however, the dielectric material layer to be measured is deposited over one or more other dielectric material layers, the optical measurement of the thickness may be difficult. Variations in the underlying dielectric material layer thickness(es) and the thickness of the dielectric material layer to be measured may be difficult and sometimes impossible to distinguish on the basis of optical spectra. In situations where optical measurements are difficult or impossible to implement, destructive measurement techniques are typically used, such as examining a cross-section of the semiconductor wafer using a scanning electron microscope (SEMS).

For these and other reasons, there is a need for the present invention.

### SUMMARY

One embodiment of the present invention provides a semiconductor wafer. The semiconductor wafer includes a first dielectric layer, a second dielectric layer contacting the first dielectric layer, and a measurement area feature. The measurement area feature is laterally enclosed by the second dielectric layer. The measurement area feature is adapted to be used for determining a thickness of the first dielectric layer, and the measurement area feature includes a mixture of at least two materials.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of an optical measurement system for determining the thickness of a dielectric material layer.

FIG. 2 illustrates a cross-sectional view of one embodiment of a semiconductor wafer including a measurement area feature.

FIG. 3A illustrates a cross-sectional view of one embodiment of a preprocessed wafer.

FIG. 3B illustrates a cross-sectional view of one embodiment of the preprocessed wafer after etching an opening in the preprocessed wafer.

FIG. 4A illustrates a cross-sectional view of one embodiment of a preprocessed wafer after etching openings in the preprocessed wafer.

FIG. 4B illustrates a cross-sectional view of one embodiment of the preprocessed wafer after depositing a material in the openings.

FIG. 5 illustrates a cross-sectional view of one embodiment of the preprocessed wafer and a measurement area feature.

FIG. 6 illustrates a cross-sectional view of one embodiment of the preprocessed wafer, measurement area feature, and device feature material layer.

FIG. 7 illustrates a cross-sectional view of one embodiment of the preprocessed wafer, measurement area feature, and device features after etching the device feature material layer.

FIG. 8 illustrates a cross-sectional view of one embodiment of the preprocessed wafer, measurement area feature, device features, and a dielectric material layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

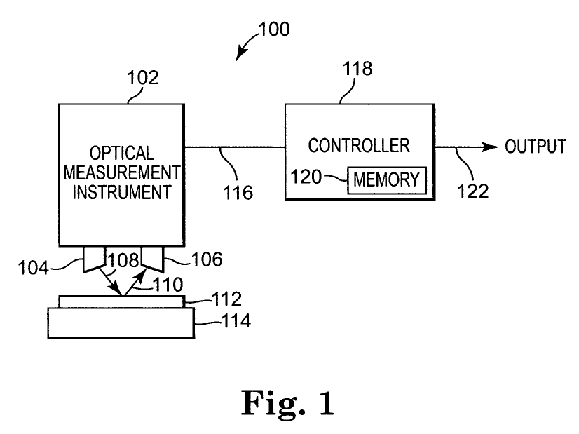

FIG. 1 is a block diagram illustrating one embodiment of an optical measurement system 100 for determining the thickness of a dielectric material layer. Optical measurement system 100 provides a non-destructive and non-contact method for determining the thickness of a first dielectric material layer deposited on a sample 112. The first dielectric material layer is deposited over a second dielectric material layer, which makes typical optical measurements for determining the thickness of the first dielectric material layer difficult or impossible. Sample 112, however, includes one or more measurement area features within the second dielectric material layer. Each measurement area feature has a top surface in contact with the bottom surface of the first dielectric material layer. Each measurement area feature enables measurement system 100 to accurately measure the thickness of the first dielectric material layer using ellipsometry, reflectometry, or other suitable optical measurement technique.

Optical measurement system 100 includes an optical measurement instrument 102, a stage 114, and a controller 118. Optical measurement instrument 102 includes a light source 104 and a detector 106. A sample, such as a product wafer 112 including a dielectric material layer, is positioned on stage 114 for analysis by optical measurement instrument 102. Optical measurement instrument 102 is electrically coupled to controller 118 through communication link 116. In one embodiment, controller 118 includes a memory 120 for storing measurement data. Controller 118 provides an output (OUTPUT) signal on OUTPUT signal path 122 indicating the thickness of the dielectric material layer.

Sample 112 includes a first dielectric material layer deposited over a second dielectric material layer. Each measurement area feature has a top surface in contact with the bottom surface of the first dielectric material layer. The top surface of each measurement area feature is coplanar with the top surface of the second dielectric material layer. Each measurement area feature enables optical measurement instrument 102 to measure the thickness of the first dielectric material layer by focusing measurement instrument 102 on the measurement area feature.

In one embodiment, the first dielectric material layer includes an oxide, such as SiO₂, or other suitable dielectric material, and the second dielectric material layer includes boro-phosphorous silicate glass (BPSG) or other suitable dielectric material. In one embodiment, each measurement area feature includes a mixture of a metal and the second dielectric material. In one embodiment, the mixture includes tungsten and BPSG. In other embodiments, the mixture includes other suitable materials. In any case, the mixture has an effective index of refraction different than the index of refraction of the first dielectric material such that the thickness of the first dielectric material layer can be determined based on optical spectra.

In the region of each measurement area feature, due to the difference in refractive indices, the interface between the first dielectric material layer and the second dielectric material layer is observable in optical spectra as utilized in ellipsometry, reflectometry, etc. This allows the measurement of the first dielectric material layer to be performed. In regions where the measurement area features are not present, the refractive indices of the first and second dielectric material layers are similar or close. Thus, it is more difficult to determine the thickness of the first dielectric material layer where the measurement area features are not present.

Optical measurement instrument 102 is an ellipsometer, reflectometer, or other suitable optical measurement instrument. An ellipsometer uses polarized light to characterize thin films, surfaces, and material microstructures. An ellipsometer determines the relative phase-change in a beam of reflected polarized light. A reflectometer measures reflectivity, which is the ratio of the intensity of a wave after reflection to the intensity of the wave before reflection.

Light source 104 includes a laser light source or broadband light source and optics to direct the light onto sample 112. Detector 106 includes a photodetector and optics to detect light reflected from sample 112. The angle of incidence can be either normal to the surface or off-axis. In one embodiment, optical measurement instrument 102 provides data from which the thickness of the first dielectric material layer of sample 112 can be determined to controller 118 through communication link 116. In another embodiment, optical measurement instrument 102 determines the thickness of the first dielectric material layer based on the measurement data for sample 112 and provides the thickness measurement to controller 118 through communication link 116.

Controller 118 controls the operation of optical measurement instrument 102. Controller 118 includes a microprocessor, microcontroller, or other suitable logic circuitry for controlling the operation of optical measurement instrument 102. In one embodiment, controller 118 receives the optical measurement data from optical measurement instrument 102 through communication link 116 and determines the thickness of the first dielectric material layer. In another embodiment, controller 118 receives the thickness measurement of the first dielectric material layer from optical measurement instrument 102 through communication link 116. Memory 120 stores the optical measurement data or the thickness measurement for the first dielectric material layer. In one embodiment, controller 118 outputs the thickness of the first dielectric material layer on OUTPUT signal path 122.

In operation, a sample 112 including a first dielectric material layer, such as SiO₂, deposited over a second dielectric material layer, such as BPSG, is placed on stage 114 for analysis. Optical measurement instrument 102 directs light from light source 102 onto sample 112 over the measurement area feature as indicated at 108. Light is reflected from sample 112 as indicated at 110. Detector 106 of optical measurement instrument 102 detects the light indicated at 110 reflected from sample 112.

In one embodiment, based on the detected reflected light, optical measurement instrument 102 generates optical measurement data for determining the thickness of the first dielectric material layer of sample 112. In another embodiment, based on the detected reflected light, optical measurement instrument 102 determines the thickness of the first dielectric material layer of sample 112. The optical measurement data for determining the thickness of the first dielectric material layer or the thickness of the first dielectric material layer is passed to controller 118. Controller 118 determines the thickness of the first dielectric material layer based on the optical measurement data if controller 118 does not receive the thickness of the first dielectric material layer directly. In one embodiment, controller 118 outputs the thickness of the first dielectric material layer of sample 112 on OUTPUT signal path 122.

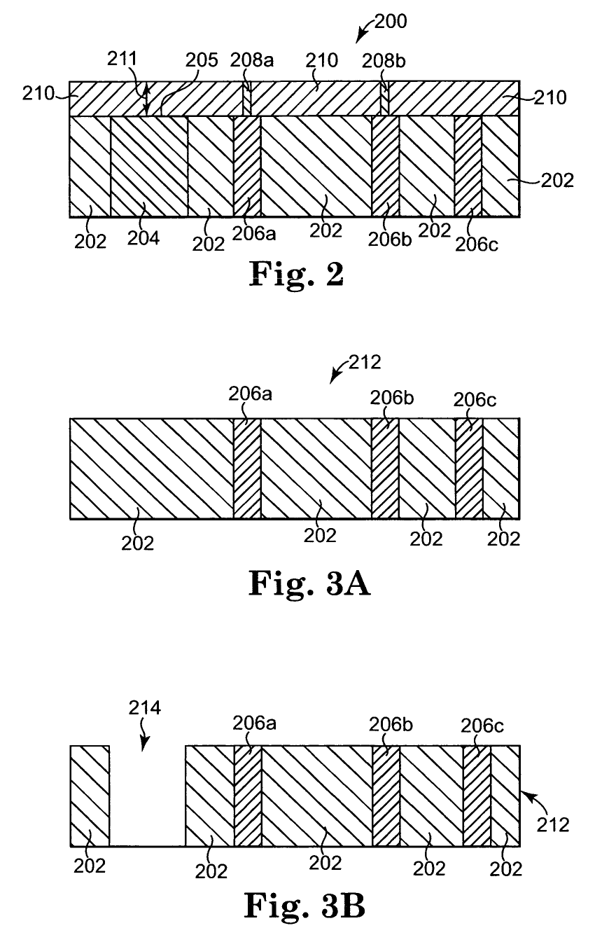

FIG. 2 illustrates a cross-sectional view of one embodiment of a semiconductor wafer 200. In one embodiment, sample 112 is similar to semiconductor wafer 200. In one embodiment, semiconductor wafer 200 is used for fabricating chips for Dynamic Random Access Memory (DRAM), Static Random Access Memory (SRAM), Phase-Change Memory (PCM), Magnetic Random Access Memory (MRAM), Flash, microprocessors, Application Specific Integrated Circuits (ASICs), Field Programmable Gate Arrays (FPGAs), or other suitable electronic devices. Semiconductor wafer 200 includes a first dielectric material layer 210, a measurement area feature 204, device features 206a-206c, 208a, and 208b, and second dielectric material layer 202.

In one embodiment, first dielectric material layer 210 includes an oxide, such as Sio₂, or other suitable dielectric material, and second dielectric material layer 202 includes BPSG or other suitable dielectric material. In one embodiment, device features 206a-206c are contact plugs, such as tungsten plugs, copper plugs, or other suitable conductive material plugs. In one embodiment, device features 208a and 208b are phase-change material for fabricating memory cells in a phase-change memory. In another embodiment, device features 208a and 208b are composed of a phase-change material and top contacting electrodes for fabricating memory cells in a phase-change memory. In another embodiment, device features 208a and 208b are composed of phase-change material and bottom contacting electrodes for fabricating memory cells in a phase-change memory. In another embodiment, device features 208a and 208b are composed of a phase-change material and top contacting electrodes and bottom contacting electrodes for fabricating memory cells in a phase-change memory. In another embodiment, device features 208a and 208b are composed of one or more phase-change materials and appropriate top contacting electrodes and bottom contacting electrodes for fabricating memory cells in a phase-change memory. In other embodiments, devices features 206a-206c and device features 208a and 208b are any suitable device features located in adjacent dielectric material layers.

Device features 208a and 208b are positioned above and contacting device features 206a and 206b, respectively. Device features 206a-206c and measurement area 204 are laterally enclosed by second dielectric material layer 202. Device features 208a and 208b are laterally enclosed by first dielectric material layer 210. The bottom surface of first dielectric material layer 210 contacts the top surface of second dielectric material layer 202, the top surface of measurement area feature 204, and top portions of device features 206a-206c.

In one embodiment, measurement area feature 204 includes a mixture of a metal and second dielectric material 202. In one embodiment, measurement area feature 204 is tungsten or other material that may be the same or similar to the material contained in device features 206a-206c. In one embodiment, measurement area feature 204 includes a mixture of tungsten and BPSG. In other embodiments, measurement area feature 204 includes a mixture of other suitable materials that provide an effective index of refraction different from the index of refraction of second dielectric material 202 such that the thickness 211 of first dielectric material layer 210 can be determined based on optical spectra. Measurement area feature 204 increases the difference in the refractive indices at interface 205 between first dielectric material layer 210 and second dielectric material layer 202. Increasing the difference in the refractive indices at interface 205 is achieved by incorporating features with higher or lower refractive indices than first dielectric material layer 210 in measurement area feature 204.

In some situations, due to processing constraints, measurement area feature 204 cannot be a single large feature using the same material as device features 206a-206c, such as tungsten, since measurement area feature 204 would not fill in a similar manner as device features 206a-206c. Therefore, the top surface of measurement feature 204 would not be coplanar with the top surface of second dielectric material layer 202. Accordingly, an optical measurement of thickness 211 of first dielectric material layer 210 at measurement area feature 204 would provide an inaccurate thickness measurement.

The following FIGS. 3-8 illustrate embodiments of a method for fabricating semiconductor wafer 200. FIG. 3A illustrates a cross-sectional view of one embodiment of a preprocessed wafer 212. Preprocessed wafer 212 includes second dielectric material layer 202, device features 206a-206c, and lower wafer layers (not shown). In one embodiment, device features 206a-206c are contact plugs, such as tungsten plugs, copper plugs, or other suitable conductive material plugs. In other embodiments, device features 206a-206c are other suitable features of an electronic device. In one embodiment, second dielectric material layer 202 includes SiO₂, fluorinated silica glass (FSG), BPSG, or other suitable dielectric material.

FIG. 3B illustrates a cross-sectional view of one embodiment of preprocessed wafer 212 after etching an opening 214 in preprocessed wafer 212. Opening 214 is etched in second dielectric material layer 202. In one embodiment, opening 214 extends to the bottom of second dielectric material layer 202. Openings, such as opening 214, are etched in multiple locations on preprocessed wafer 212. In one embodiment, openings are etched in a few locations, such as three or four locations, on preprocessed wafer 212. In another embodiment, openings are etched for every chip on preprocessed wafer 212. In other embodiments, any suitable number of openings are etched based on the number of locations a dielectric material layer thickness measurement is to be made.

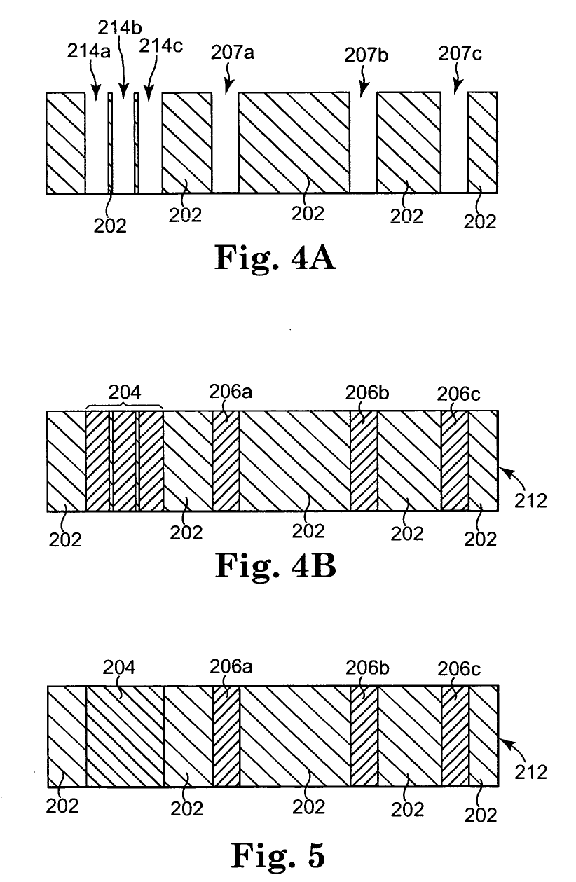

FIGS. 4A and 4B illustrate another embodiment of steps in the method for fabricating semiconductor wafer 200. FIG. 4A illustrates a cross-sectional view of one embodiment of a preprocessed wafer after etching openings in the preprocessed wafer. In contrast to preprocessed wafer 212 illustrated in FIG. 3A, in this embodiment, device features 206a-206c are formed simultaneously with measurement area feature 204. Openings 214a-214c and openings 207a-207c are etched in second dielectric material layer 202. Openings 214a-214c are for forming measurement area feature 204, and openings 207a-207c are for forming device features 206a-206c.

In one embodiment, openings 214a-214c and openings 207a-207c extend to the bottom of second dielectric material layer 202. Openings 214a-214c are etched in multiple locations on the preprocessed wafer. In one embodiment, the openings are etched in a few locations, such as three or four locations, on the preprocessed wafer. In another embodiment, the openings are etched for every chip on the preprocessed wafer. In other embodiments, the openings are etched at any suitable number of locations based on the number of locations a dielectric material layer thickness measurement is to be made.

In one embodiment, openings 214a-214c are similar in width to openings 207a-207c, but the distance between openings 214a-214c is less than the distance between openings 207a-207c. In another embodiment, the widths of openings 214a-214c are greater than or less than the widths of openings 207a-207c. While three openings 214a-214c are illustrated, any suitable number of openings can be used. In one embodiment, the lateral dimension of openings 214a-214c is varied within processing specifications. In one embodiment, the arrangement of openings 214a-214c is aperiodic of same size opening in a field of second dielectric material 202. The resulting measurement area feature 204 thus formed will be composed of laterally distinct regions some of which will be of the same material as device features 206a-206c and the remainder the same material as second dielectric material layer 202.

FIG. 4B illustrates a cross-sectional view of one embodiment of the preprocessed wafer after depositing a material in openings 214a-214c and openings 207a-207c. In one embodiment, tungsten or another suitable material is deposited into openings 214a-214c and openings 207a-207c to provide measurement area feature 204 and device features 206a-206c. The material is deposited using chemical vapor deposition (CVD), atomic layer deposition (ALD), metal organic chemical vapor deposition (MOCVD), plasma vapor deposition (PVD), jet vapor deposition (JVP), or other suitable deposition technique.

FIG. 5 illustrates a cross-sectional view of one embodiment of preprocessed wafer 212 and a measurement area feature 204. In one embodiment, a single material with an optical refractive index distinct from dielectric material 202 is deposited into opening 214 (FIG. 3B) to provide measurement area feature 204. In another embodiment, a mixture of at least two materials is deposited into opening 214 (FIG. 3B) to provide measurement area feature 204. In one embodiment, a mixture of the material used to form device features 206a-206c and second dielectric material 202 is deposited into opening 214 to provide measurement area feature 204. In another embodiment, a mixture of tungsten and BPSG is deposited into opening 214 to provide measurement area feature 204. In other embodiments, a suitable mixture of at least two materials that provide an effective index of refraction different than dielectric material 202 is deposited into opening 214 to provide measurement area feature 204. The mixture of material is selected such that the thickness of a dielectric material layer deposited on second dielectric material layer 202 can be determined based on optical spectra. In another embodiment, the mixture of material is formed as previously described and illustrated with reference to FIGS. 4A and 4B.

In one embodiment, the effective refractive index of measurement area feature 204 is determined using an effective medium approach. In the effective medium approach, layers within homogeneous structures are modeled as homogeneous layers with modeled refractive indices. The effective refractive index is then calculated using the indices of the constituent materials, with weighting factors. In another embodiment, the effective refractive index is determined as a fitting parameter without resorting to knowledge of the indices of the constituent materials.

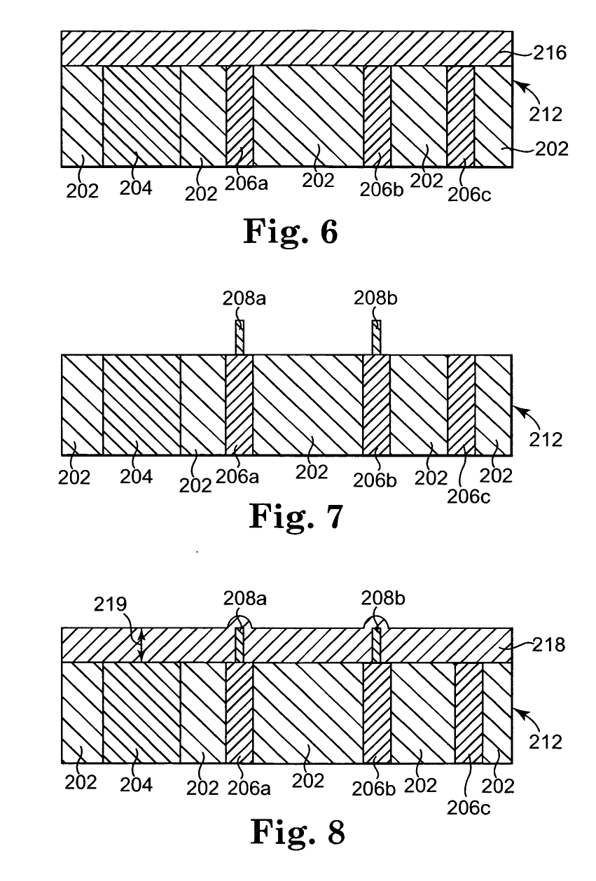

FIG. 6 illustrates a cross-sectional view of one embodiment of preprocessed wafer 212, measurement area feature 204, and a device feature material layer 216. In one embodiment, device feature material layer 216 is a layer of phase-change material. In other embodiments, device feature material layer 216 is a layer of other suitable material for forming device features. Device feature material, such as phase-change material, metal, insulation material, or other suitable device feature material, is deposited over preprocessed wafer 212 and measurement area feature 204 to provide device feature material layer 216. Device feature material layer 216 is deposited using CVD, ALD, MOCVD, PVD, JVP, or other suitable deposition technique.

FIG. 7 illustrates a cross-sectional view of one embodiment of preprocessed wafer 212, measurement area feature 204, and device features 208a and 208b after etching device feature material layer 216. Device feature material layer 216 is etched to provide device features 208a and 208b. Device feature 208a contacts device feature 206a, and device feature 208b contacts device feature 206b. In one embodiment, device features 208a and 208b are phase-change material features for fabricating memory cells for a phase-change memory. In other embodiments, device features 208a and 208b are other suitable device features for fabricating an electronic device.

FIG. 8 illustrates a cross-sectional view of one embodiment of preprocessed wafer 212, measurement area feature 204, device features 208a and 208b, and a dielectric material layer 218. A dielectric material, such as SiO₂, FSG, BPSG, or other suitable dielectric material is deposited over exposed portions of preprocessed wafer 202, measurement area feature 204, and device features 208a and 208b to provide dielectric material layer 218. Dielectric material layer 218 is deposited using CVD, ALD, MOCVD, PVD, JVP, or other suitable deposition technique.

Dielectric material layer 218 has a thickness, as indicated at 219, which can be measured by optical measurement system 100 at measurement area feature 204. Dielectric material layer 218 is planarized to provide first dielectric material layer 210 of semiconductor wafer 200 as previously described and illustrated with reference to FIG. 2. Dielectric material layer 218 is planarized using chemical mechanical planarization (CMP) or other suitable planarization process. The planarization process can be controlled by measuring the thickness 219 of dielectric material layer 218 before planarization and the thickness 211 of first dielectric material layer 210 after planarization.

Embodiments of the present invention provide a method for measuring the thickness of a dielectric material layer that has been deposited over another dielectric material layer. Unlike cross-section SEMS, embodiments of the present invention do not destroy the semiconductor wafer. In addition, embodiments of the present invention can be implemented on product wafers. Further, the present invention can be used during in-line processing of product wafers. High sampling frequencies for both the number of wafers for determining processing drifts and the number of sites per wafer for determining process uniformity is possible.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor wafer comprising:
a first dielectric layer;
a second dielectric layer contacting the first dielectric layer; and
a measurement area feature laterally enclosed by the second dielectric layer, the measurement area feature adapted to be used for determining a thickness of the first dielectric layer, the measurement area feature comprising a mixture of at least two materials.

2. The semiconductor wafer of claim 1, wherein the mixture comprises a metal and a dielectric material.

3. The semiconductor wafer of claim 1, wherein the mixture comprises tungsten and boro-phosphorous silicate glass.

4. The semiconductor wafer of claim 1, wherein the first dielectric layer comprises an oxide layer and the second dielectric layer comprises a boro-phosphorous silicate glass layer.

5. The semiconductor wafer of claim 1, wherein the mixture comprises portions of the second dielectric layer and at least one other material.

6. The semiconductor wafer of claim 1, wherein an effective refractive index of the mixture is different from a refractive index of the first dielectric layer such that the thickness of the first dielectric layer can be determined based on optical spectra.

7. A semiconductor wafer comprising:
a first device feature;
a second device feature contacting the first device feature;
a measurement area feature comprising a mixture of a metal and a dielectric material;
a first dielectric material layer laterally enclosing the first device feature; and
a second dielectric material layer laterally enclosing the second device feature and the measurement area feature,
wherein the measurement area feature is adapted to be used for determining a thickness of the first dielectric material layer.

8. The semiconductor wafer of claim 7, wherein the measurement area feature comprises a mixture of tungsten and boro-phosphorous silicate glass.

9. The semiconductor wafer of claim 7, wherein the first dielectric material layer comprises an oxide and the second dielectric material layer comprises boro-phosphorous silicate glass.

10. The semiconductor wafer of claim 7, wherein the mixture comprises portions of the second dielectric material layer and at least one other material.

11. The semiconductor wafer of claim 7, wherein an effective refractive index of the mixture is different from a refractive index of the first dielectric material layer such that the thickness of the first dielectric material layer can be determined based on optical spectra.

12. A semiconductor wafer comprising:
a first dielectric material layer;
a second dielectric material layer contacting the first dielectric material layer; and
means for optically determining a thickness of the first dielectric material layer.

13. The semiconductor wafer of claim 12, wherein the first dielectric material layer comprises an oxide.

14. The semiconductor wafer of claim 12, wherein the second dielectric material layer comprises boro-phosphorous silicate glass.

15. A method for determining the thickness of a dielectric layer, the method comprising:
providing a preprocessed wafer including a first dielectric layer;
etching the first dielectric layer to provide an opening;
filling the opening with a mixture of at least two materials to provide a measurement area feature;
depositing a second dielectric layer over the preprocessed wafer and measurement area feature; and
measuring a thickness of the second dielectric layer at the measurement area feature.

16. The method of claim 15, wherein filling the opening with the mixture comprises filling the opening with a mixture having an effective refractive index different than a refractive index of the second dielectric layer such that the thickness of the second dielectric layer can be determined based on optical spectra.

17. The method of claim 15, further comprising:
determining an effective refractive index of the mixture,
wherein measuring the thickness of the second dielectric layer comprises measuring the thickness of the second dielectric layer based on the effective refractive index.

18. The method of claim 15, wherein filling the opening with the mixture comprises filling the opening with a mixture of tungsten and boro-phosphorous silicate glass.

19. The method of claim 15, wherein depositing the second dielectric layer comprises depositing an oxide layer.

20. The method of claim 15, wherein providing the preprocessed wafer comprises providing the preprocessed wafer including a boro-phosphorous silicate glass layer.

21. A method for determining the thickness of a dielectric material layer, the method comprising:
providing a preprocessed wafer including a first dielectric material layer;
etching the first dielectric material layer to provide device feature openings and measurement area feature openings;
filling the device feature openings and measurement area feature openings with a material to provide device features and measurement area features such that an effective refractive index of the measurement area features is different than a refractive index of the first dielectric material;
fabricating second device features contacting the first device features;
depositing a second dielectric material layer over exposed portions of the preprocessed wafer and the second device features; and
measuring a thickness of the second dielectric material layer at a measurement area feature.

22. The method of claim 21, further comprising:
planarizing the second dielectric material layer to provide a third dielectric material layer; and
measuring a thickness of the third dielectric material layer at the measurement area feature.

23. The method of claim 21, further comprising:
determining an effective refractive index of the measurement area features,
wherein measuring the thickness of the second dielectric material layer comprises measuring the thickness of the second dielectric material based on the effective refractive index.

24. The method of claim 21, wherein filling the device feature openings and the measure area feature openings comprises filling the device feature openings and the measurement area feature openings with tungsten.

25. The method of claim 21, wherein depositing the second dielectric material layer comprises depositing an oxide layer.

26. The method of claim 21, wherein providing the preprocessed wafer comprises providing a boro-phosphorous silicate glass layer.
